(19) United States
(12) Patent Application Publication
(10) Pub. No.: US 2003/0146088 A1
(43) Pub. Date: Aug. 7, 2003

(54) Apparatus and method for forming optical coating using negatively charged ions

(75) Inventor: Daesig Kim, Pleasanton, CA (US)

Correspondence Address: MORGAN LEWIS & BOCKIUS LLP, 1111 PENNSYLVANIA AVENUE NW, WASHINGTON, DC, 20004, US

(73) Assignee: Filteray Fiber Optics, Inc.

(21) Appl. No.: 10/097,626

(22) Filed: Mar. 15, 2002

(30) Foreign Application Priority Data
Feb. 1, 2002 (KR) P2002-0005827

(51) Int. Cl. C23C 14/32

(52) U.S. Cl. 204/192.26; 204/298.07; 204/192.27; 204/192.28

(57) ABSTRACT

A method and apparatus for forming an optical coating using negatively charged ions, which form a high quality thin film of high density, are disclosed in the present invention. The apparatus includes a gas flow controller controlling an amount of an externally introduced inert gas, a pre-heater pre-heating the inert gas introduced from the gas flow controller through a first gas flow tube, a cesium vaporizer discharging a cesium gas through a third gas flow tube carried by the inert gas introduced from the pre-heater through a second gas flow tube and a bubbler, a pressure detector detecting a vapor pressure of the cesium vaporizer, a pressure control valve controlling the vapor pressure of the cesium vaporizer, a gas introduction tube introducing the cesium gas to a vacuum chamber, a plurality of targets in the vacuum chamber, and a plurality of cesium discharge units selectively discharging the cesium gas to each surface of the targets. It is emphasized that this abstract is provided to comply with the rules requiring an abstract that will allow a searcher or other reader to quickly ascertain the subject matter of the technical disclosure. It is submitted with the understanding that it will not be used to interpret or limit the scope or meaning of the claims.

This application claims the benefit of Korean Application No. 2002-0005827 filed on Feb. 01, 2002, which is hereby incorporated by reference.

### BACKGROUND OF THE INVENTION

1. Field of the Invention

The present invention relates to an apparatus and method for forming a coating, and more particularly, to an apparatus and method for forming an optical coating using negatively charged ions. Although the present invention is suitable for a wide scope of applications, it is particularly suitable for forming a high quality thin film of high density.

2. Discussion of the Related Art

In optical communication, a wavelength division multiplexing (WDM) method transmits data by using a plurality of lightwaves each having different wavelengths. This method has been applied in data transmission through optical fibers.

The wavelength division multiplexing (WDM) method requires a filter separating data signals from each lightwave. Generally, in the WDM method, a multi-layered thin film is used as a filter.

More specifically, as shown in FIG. 1, a filter including a SiO₂ thin film 2 and a Ta₂O₅ thin film 3 both deposited on a substrate 1 and a resonator 4 is used for a dense wavelength division multiplexing (DWDM) method, whereby gaps between the lightwaves are as small as about 0.01 μm. Each thin film is formed of ¼λ, which is an optical thickness corresponding to ¼ of the wavelength.

In C-band, a thin film layer is formed at a thickness of about 200 to 300 nm. The thickness of the multi-layered thin film increases with the increase in the number of channels used.

In order to form a multi-layered thin film, several hundreds of layers are alternatively deposited on a substrate. Generally, an e-beam evaporation method or a sputtering method is used in the process. Herein, the sputtering method is advantageous in forming thin films of both metallic and insulating layers. More specifically, the fabrication process is carried out with high energy, thereby enabling the thin film to have a strong adhesion and an excellent step coverage so as to form a uniform thin film.

A related art apparatus and method for forming an optical coating by using an apparatus for sputtering will be described in detail with reference to the accompanying drawings.

FIG. 2 is a schematic view of the related art apparatus for sputtering using a multi-target apparatus. FIG. 3 is a flow chart illustrating a deposition method used in the apparatus for sputtering in FIG. 2.

As shown in FIG. 2, the related art apparatus for sputtering for forming a multi-layered thin film for DWDM includes a vacuum chamber 21, first and second targets 22a and 22b both spaced apart from a substrate within the vacuum chamber, a power supplying unit (not shown) applying power to the first and second targets 22a and 22b, and a plasma generating unit 23 supplying a plasma source into the vacuum chamber 21. Herein, the first and second targets 22a and 22b are each formed of source materials for a SiO₂ thin film and a Ta₂O₅ thin film. An inert gas such as argon is used as a plasma source.

In the related art apparatus for sputtering having the above-described structure, the vacuum chamber 21 is filled with an inert gas, such as argon. A high voltage of DC or a radio frequency (RF) is applied to the targets, thereby ionizing the argon gas. When the ionized argon gas collides with the targets, the thin films are formed by using the generated ions.

The deposition method of a multi-layered thin film for DWDM using the apparatus for sputtering will be described in detail.

As shown in FIG. 3, when depositing a Ta₂O₅ thin film, a constant pressure is maintained in the vacuum chamber 21. A plasma source (i.e., argon gas) is introduced therein, and power is applied to the first target 22a. Herein, the argon gas around the surface of the first target 22a is ionized as a form of plasma.

With high energy, the ionized argon gas collides with the first target 22a. The ionized metallic ions are then sputtered to form a metallic thin film on the substrate 24. Simultaneously, diluted oxygen gas is supplied to the substrate to induce a reaction between the metal deposited on the substrate and the oxygen gas, thereby forming a Ta₂O₅ thin film.

Subsequently, after the deposition process of a Ta₂O₅ thin film, the power supplied to the first target 22a is turned off. The supply of the plasma source is also cut off. Then, the plasma source is supplied again, and the power is supplied to the second target 22b in order to form a SiO₂ thin film by using a deposition method similar to that of the Ta₂O₅ thin film.

However, when forming a thin film with the method and apparatus for sputtering using the multi-target apparatus, the qualities required in the thin film, such as surface roughness, density, and interfacial characteristic, do not fulfill the requirements when forming a multi-layered thin film for DWDM. Therefore, an auxiliary equipment using plasma in order to produce ion beam is used. However, problems remain yet to be resolved for forming a DWDM multi-layered thin film applicable to a frequency of at least 100 GHz.

### SUMMARY OF THE INVENTION

Accordingly, the present invention is directed to an apparatus and method for forming an optical coating using negatively charged ions that substantially obviate one or more of problems due to limitations and disadvantages of the related art.

Another object of the present invention is to provide an apparatus and method for forming an optical coating using negatively charged ions that use bubbles produced from an inert gas so as to selectively supply cesium gas to a plurality of targets within a vacuum chamber.

Another object of the present invention is to provide an apparatus and method for forming an optical coating using negatively charged ions that produce negatively charged ions from the targets when forming a multi-layered thin film so as to form a high quality thin film of high density and to increase a deposition rate.

Additional features and advantages of the invention will be set forth in the description which follows and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, an apparatus for forming an optical coating includes a gas flow controller controlling an amount of an externally introduced inert gas, a pre-heater pre-heating the inert gas introduced from the gas flow controller through a first gas flow tube, a cesium vaporizer discharging a cesium gas through a third gas flow tube carried by the inert gas introduced from the pre-heater through a second gas flow tube and a bubbler, a pressure detector detecting a vapor pressure of the cesium vaporizer, a pressure control valve controlling the vapor pressure of the cesium vaporizer, a gas introduction tube introducing the cesium gas to a vacuum chamber, a plurality of targets in the vacuum chamber, and a plurality of cesium discharge units selectively discharging the cesium gas to each surface of the targets.

In another aspect of the present invention, a method for forming an optical coating on a substrate using an apparatus for sputtering first and second targets and first and second cesium discharge units each adjacent to the first and second targets, includes forming a first thin film by simultaneously applying a power to the first target and discharging a cesium gas through the first cesium discharge unit, cutting off the power applied to the first target and the cesium gas applied to the first cesium discharge unit, forming a second thin film on the first thin film by simultaneously applying power to the second target and discharging the cesium gas through the second cesium discharge unit, cutting off the power applied to the second target and the cesium gas applied to the second cesium discharge unit, and repeating the forming the first and second thin films until desired layers are formed on the substrate.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention.

In the drawings:

FIG. 1 is a cross-sectional view illustrating a thin film type DWDM filter;

FIG. 2 is a schematic view of an apparatus for sputtering using a multi-target method of the related art;

FIG. 3 is a flow chart illustrating a deposition process using the apparatus for sputtering in FIG. 2;

FIG. 4 is a schematic view illustrating an apparatus for forming an optical coating according to the present invention; and

FIG. 5 is a flow chart illustrating a deposition process using the apparatus for forming an optical coating in FIG. 4.

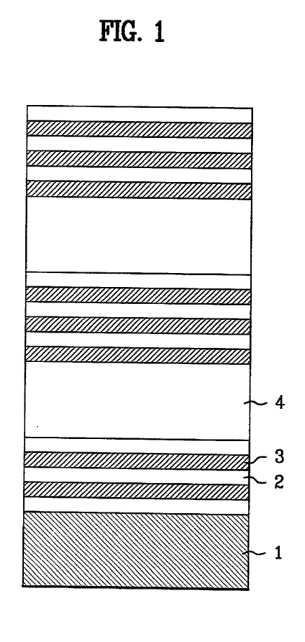

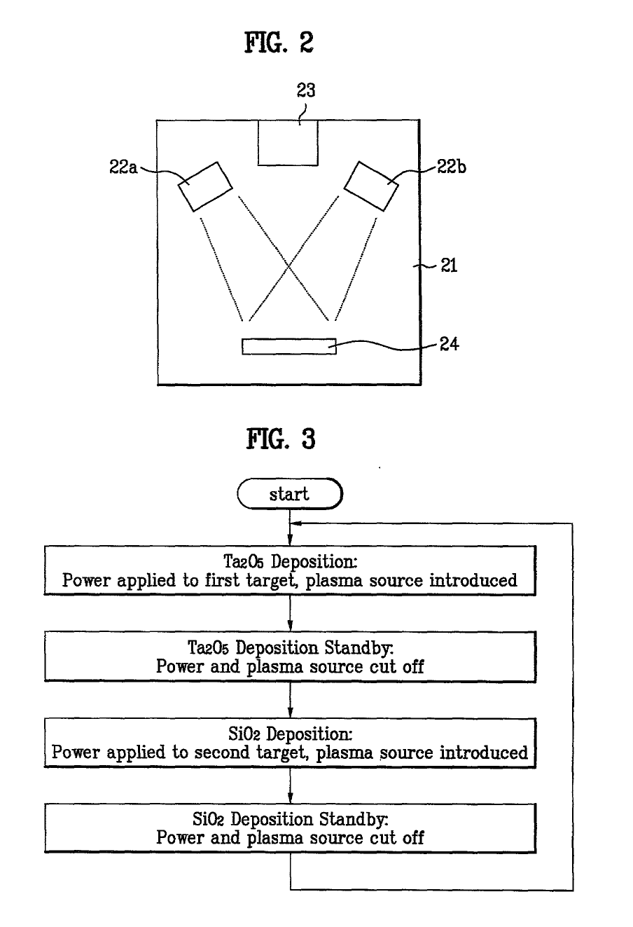

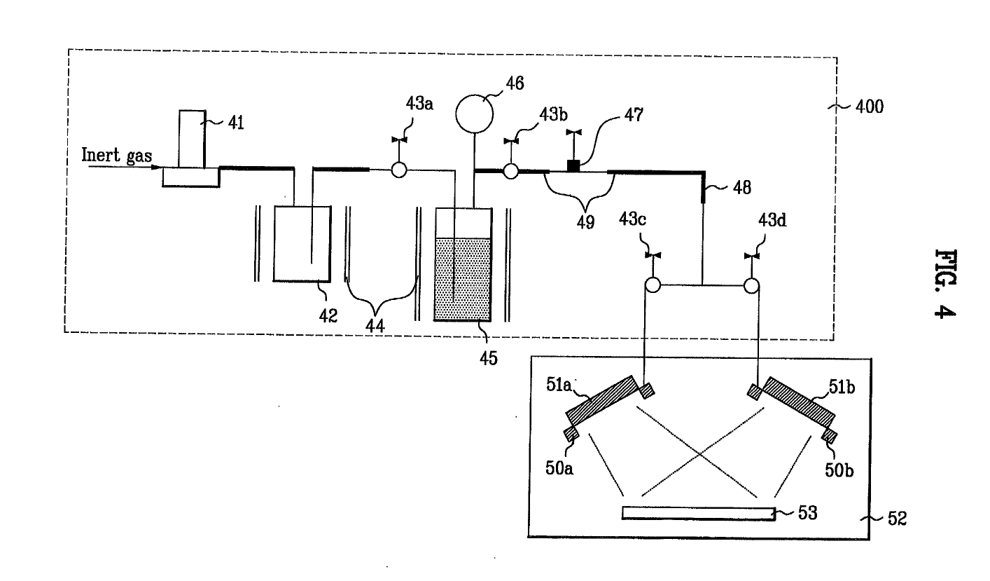

### DETAILED DESCRIPTION OF THE ILLUSTRATED EMBODIMENTS

Reference will now be made in detail to the illustrated embodiments of the present invention, examples of which are illustrated in the accompanying drawings. Wherever possible, the same reference numbers will be used throughout the drawings to refer to the same or like parts.

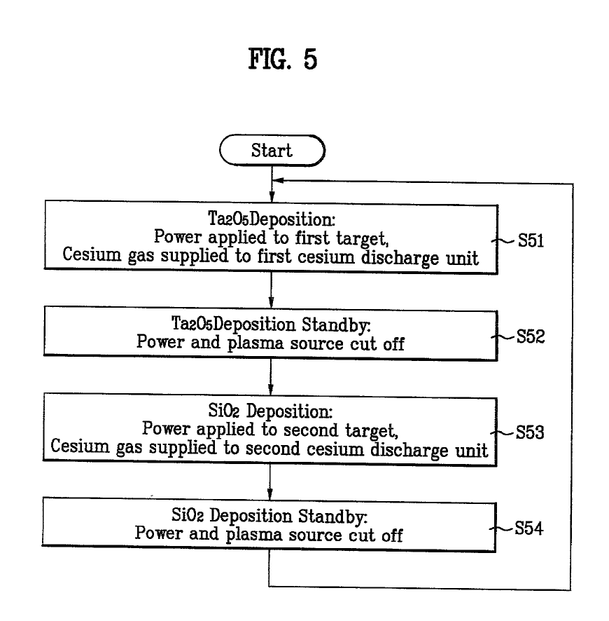

FIG. 4 is a schematic view illustrating an apparatus for forming an optical coating according to the present invention. FIG. 5 is a flow chart illustrating a deposition process using the apparatus for forming an optical coating in FIG. 4.

As shown in FIG. 4, the apparatus for forming an optical coating using a multi-target apparatus according to the present invention includes a vacuum chamber 52, first and second targets 51a and 51b, first and second cesium discharge units 50a and 50b each adjacent to the first and second targets 51a and 51b and discharging cesium gas, and a cesium supplying unit 400 selectively supplying cesium gas to the first and second cesium discharge units 50a and 50b.

The apparatus further includes a power supplying unit (not shown) supplying power to the first and second targets 51a and 51b and a plurality of magnets (not shown) formed on each rear surface of the first and second targets 51a and 51b.

The first and second targets 51a and 51b are sources for forming the Ta₂O₅ thin film and the SiO₂ thin film. The targets 51a and 51b are spaced apart at a distance from the substrate 53.

Herein, the apparatus 400 for supplying cesium includes a gas flow controller 41 controlling the amount of externally introduced inert gas, a pre-heater 42 pre-heating the inert gas introduced through a first gas flow tube from the gas flow controller 41, a cesium vaporizer 45 emitting cesium gas to a third gas flow tube by using the inert gas introduced through a second gas flow tube from the pre-heater 42 and a bubbler, a pressure detector 46 detecting vapor pressure of the cesium vaporizer 45, a pressure control valve 47 controlling vapor pressure of the cesium vaporizer 45 by opening and closing the third gas flow tube, and a gas introduction tube 48 selectively introducing the cesium gas, which is passed through the pressure control valve 47, to the first and second cesium discharge units 50a and 50b.

The apparatus further includes a first cutoff valve 43a supplying and cutting off the inert gas supplied to the cesium vaporizer 45 to the pre-heater 42, a second cutoff valve 43b supplying and cutting off the cesium gas emitted to the third gas flow tube from the cesium vaporizer 45, third and fourth cutoff valves 43c and 43d each opening and closing the gas introduction tube 48, which is separately connected to the first and second cesium discharge units 50a and 50b, a heater 44 heating the pre-heater 42 and the cesium vaporizer 45, and a plurality of heating wires heating the first, second, and third gas flow tubes.

In addition to argon (Ar), nitrogen (N₂) and helium (He) may also be used as an inert gas. Furthermore, the cesium vaporizer 45 may be filled with one of liquid cesium, solid cesium, and a cesium compound formed of a mixture of liquid cesium and solid cesium.

In the cesium vaporizer 45, when the liquid cesium is used as filling, one side of the second gas flow tube may be positioned inside the liquid cesium and the other side of the third gas flow tube may be positioned higher than the surface of the liquid cesium. Conversely, when solid cesium or a cesium compound, which is formed by mixing solid cesium and liquid cesium, is used as filling, the second gas flow tube and the third gas flow tube may be installed in an order opposite to that of the liquid cesium.

The deposition process of a multi-layered thin film by using an apparatus for sputtering having the above-described structure will be described in detail.

As shown in FIG. 5, when depositing the Ta₂O₅ thin film, a constant pressure is maintained in the vacuum chamber 52. Cesium gas is discharged through the first cesium discharge unit 50a installed above the first target 51a. For Example, the first cesium discharge unit 50a may have a ring shape for uniform distribution of cesium over the target. Simultaneously, one of DC, pulse DC, and RF power is applied to the first target 51a (S51).

Herein, the apparatus 400 for supplying cesium supplies the cesium gas mixed with an inert gas. In order to selectively supply the cesium gas only to the first cesium discharge unit 50a, the fourth cutoff valve 43d cuts off the cesium gas introduced to the second cesium discharge unit 50b.

The first cesium discharge unit 50a discharges the mixture of the cesium gas and the inert gas to the vacuum chamber 52. Due to a glow discharge from the surface of the first target 51a, the mixture of the cesium gas and the inert gas is changed into a form of ionized gas, more specifically, a form of plasma. The plasma formed of the cesium gas mixed with the inert gas collides with the first target 51a, thereby providing high energy to the targets.

Target particles sputtered by the inert gas are neutral, but those sputtered by cesium become ions with negative charge having inherent high energy. These two kinds of sputtered particles are deposited onto the substrate 53. Oxygen gas is then supplied to induce a reaction between the metal deposited on the substrate and the oxygen gas, thereby forming the Ta₂O₅ thin film (S51).

When the deposition process of the Ta₂O₅ thin film is completed, the power supplied to the first target 51a is turned off. Then, the third cesium cutoff valve 43c cuts off the cesium gas supplied to the first cesium discharge unit 50a (S52).

Subsequently, in order to deposit the SiO₂ thin film, cesium is discharged through the second cesium discharge unit 50b installed around the second target 51b. Simultaneously, one of DC, pulse DC, and RF power is applied to the second target 51b (S53).

The fourth cutoff valve 43d opens the gas introduction tube 48 connected to the second cesium discharge unit 50b for selectively supplying the cesium gas only to the second cesium discharge unit 50b.

Then, power is applied to the second target 51b, which deposits target particles onto the Ta₂O₅ thin film by using the plasma formed of a mixture of the cesium and the inert gas. Simultaneously, the second target 51b supplies oxygen gas to form the SiO₂ thin film.

When the deposition process of the SiO₂ thin film is completed, the power supplied to the second target 51b and the cesium gas supplied to the second cesium discharge unit 50b is cut off (S54).

The above-described process of depositing the Ta₂O₅ thin film and the SiO₂ thin film is repeated until a desired form of multi-layered thin film is achieved.

The operation of the apparatus 400 for supplying cesium, which supplies cesium gas to the first and second cesium discharge units 50a and 50b will be described in detail.

As shown in FIG. 5, a heater 44 installed on the circumferential surface of the pre-heater 42 pre-heats the gas introduced to the pre-heater 42 from the gas flow controller 41. The pre-heated gas is introduced with the cesium vaporizer 45 through the second gas flow tube. Due to the gas, the liquid cesium filled within the cesium vaporizer 45 produces bubbles.

Due to the heater 44 installed on the circumferential surface of the cesium vaporizer 45, the cesium is vaporized. The cesium vapor is adsorbed onto the surface of the argon gas bubbles, which are then discharged through the third gas flow tube and, finally, introduced to the vacuum chamber 52 through the gas introduction tube 48.

Herein, the cesium vaporizer 45 is heated by the heater 44 at a temperature ranging from about 80 to 250° C. and vaporizes the cesium. The heating wires 49 maintain the first, second, and third gas flow tubes at about the same temperature. The entire apparatus for supplying cesium, except for the gas flow controller 41 and the third gas flow tube, may also be inserted within a heating oven in order to uniformly control the temperature.

An optimum temperature for obtaining a desired amount of cesium gas may vary between the range of 40 to 300° C. depending on the processing pressure. In the present invention, the processing pressure is the pressure at a plasma forming region, which is between the order of mTorr and Torr, thereby being heated at the temperature ranging from about 80 to 250° C. In addition, the pressure detector 46 and the pressure control valve 47 are sequentially controlled. Thus, the amount of cesium gas to be supplied into the chamber may be adequately controlled according to the change in the processing pressure and the pressure of the entire system.

Therefore, the amount of thermodynamically vaporized cesium is determined by stabilizing the temperature and pressure of the cesium vaporizer 45. By bubbling the argon gas, the amount of cesium gas may be supplied and controlled more accurately.

More specifically, the gas introduction tube 48 is maintained at a temperature higher than that of the entire system excluding the gas flow controller 41. Thus, clogging of solid cesium in the gas introduction tube caused by cesium oxidation may be prevented. The same problem of clogging caused by cesium oxidation occurring in the related art may also be prevented. Therefore, the supply of cesium to the vacuum chamber becomes more stable.

The pressure detector 46 measures the vapor pressure of the cesium vaporizer 45. The pressure control valve 47 is controlled in accordance with the measured value. Then, the vapor pressure of the cesium vaporizer 45 is controlled.

The amount of cesium gas supplied to the vacuum chamber 52 depends on the amount of argon bubbles and the cesium vaporization. The spread of cesium gas over a substrate also depends on the flux of the argon gas. Moreover, by blowing an inert gas, a counter flow of oxygen or other oxidizing substances from the vacuum chamber 52 into the cesium discharging line may also be prevented. Thus, cesium vapor may be obtained for a long-term period without any deterioration.

Therefore, by controlling the gas flow controller 41, the amount of the inert gas may be accurately regulated. Additionally, by controlling the pressure control valve 47 and the heater 44, the amount of cesium vaporization may be regulated.

More specifically, when using the apparatus 400 for supplying cesium according to the present invention, cesium gas can be provided stably and continuously for a long period of time at a lower temperature.

As described above, the apparatus and method for sputtering according to the present invention supplies cesium gas with inert gas, whereby the cesium gas generates negatively charged ions from the targets. Thus, the target particles having negative charge are formed onto a substrate as a thin film, thereby enabling a fast deposition rate as well as forming a high quality thin film of high density. In addition, magnets adjacent to a target and forming a line of magnetic force increases the discharge of target particles, thereby increasing the thin film deposition rate.

The apparatus and method for forming an optical coating has the following advantages.

By using bubbles produced from an inert gas, cesium gas is supplied to the surfaces of a plurality of targets within a vacuum chamber. When forming a multi-layered thin film, the targets generate a number of negatively charged ions in high energy, thereby forming a high quality thin film of high density.

Additionally, by using magnets producing a line of magnetic force accelerating plasma formation, the emission of target particles may be enhanced, thereby increasing the deposition rate.

Furthermore, by using a heater or a plurality of heating wires in the entire system for supplying cesium, a constant amount of cesium gas may be supplied to the vacuum chamber. Also, by using a valve between gas introduction tubes, the cesium gas may be selectively supplied to each cesium discharge unit.

Finally, by using an inert gas as a carrier to supply the cesium gas, the supplied amount of the cesium gas may be accurately regulated. Thus, the discharge area may be expanded. Also, a counter flow of oxygen or other oxidizing substances into a cesium introduction tube may be avoided, thereby preventing cesium oxidation.

It will be apparent to those skilled in the art that various modifications and variations can be made in the apparatus and method for forming optical coating using negatively charged ions of the present invention without departing from the spirit or scope of the inventions. Thus, it is intended that the present invention covers the modifications and variations of this invention provided they come within the scope of the appended claims and their equivalents.

What is claimed is:

1. An apparatus for forming an optical coating, comprising:
a gas flow controller controlling an amount of an externally introduced inert gas;
a pre-heater pre-heating the inert gas introduced from the gas flow controller through a first gas flow tube;
a cesium vaporizer discharging a cesium gas through a third gas flow tube carried by the inert gas introduced from the pre-heater through a second gas flow tube and a bubbler;
a pressure detector detecting a vapor pressure of the cesium vaporizer;
a pressure control valve controlling the vapor pressure of the cesium vaporizer;
a gas introduction tube introducing the cesium gas to a vacuum chamber;
a plurality of targets in the vacuum chamber; and
a plurality of cesium discharge units selectively discharging the cesium gas to each surface of the targets.

2. The apparatus according to claim 1, wherein the plurality of targets are sources for a Ta₂O₅ thin film and a SiO₂ thin film.

3. The apparatus according to claim 1, further comprising at least one magnet is adjacent to each target.

4. The apparatus according to claim 1, further comprising a power supply unit applying one of DC, pulse DC, and RF power to each target.

5. The apparatus according to claim 1, wherein the inert gas includes one of argon, nitrogen, and helium.

6. The apparatus according to claim 1, wherein the cesium gas is generated from one of liquid cesium, solid cesium, and a cesium compound formed of a mixture of the liquid cesium and the solid cesium.

7. The apparatus according to claim 1, wherein the cesium vaporizer emits the cesium gas through a plurality of bubbles formed by the inert gas.

8. The apparatus according to claim 1, further comprising:
a heater heating the pre-heater and the cesium vaporizer; and
a plurality of heating wires heating the first, second, and third gas flow tubes.

9. The apparatus according to claim 1, further comprising:
a first cutoff valve at each of the second and third gas flow tubes; and
a second cutoff valve on the gas introduction tube for selectively supplying the cesium gas to the plurality of cesium discharge units.

10. The apparatus according to claim 1, wherein the pressure control valve controls the vapor pressure of the cesium vaporizer by opening and closing the third gas flow tube.

11. The apparatus according to claim 1, wherein the cesium vaporizer is heated at a temperature ranging from about 80 to 250° C. when a process pressure is within a plasma forming range of an order of mTorr to Torr.

12. The apparatus according to claim 1, wherein the pre-heater and the cesium vaporizer are both introduced into an oven to be heated at a temperature ranging from about 80 to 250° C. when a process pressure is within a plasma forming range of an order of mTorr to Torr.

13. The apparatus according to claim 1, wherein the gas introduction tube is heated at a temperature higher than that of the cesium vaporizer.

14. A method for forming an optical coating on a substrate using an apparatus for sputtering first and second targets and first and second cesium discharge units each adjacent to the first and second targets, the method comprising:
forming a first thin film by simultaneously applying a power to the first target and discharging a cesium gas through the first cesium discharge unit;
cutting off the power applied to the first target and the cesium gas applied to the first cesium discharge unit;
forming a second thin film on the first thin film by simultaneously applying power to the second target and discharging the cesium gas through the second cesium discharge unit;
cutting off the power applied to the second target and the cesium gas applied to the second cesium discharge unit; and
repeating the forming the first and second thin films until desired layers are formed on the substrate.
